(19) United States
(12) Patent Application Publication
(10) Pub. No.: US 2022/0119955 A1
(43) Pub. Date: Apr. 21, 2022

(54) TECHNIQUES FOR VARIABLE DEPOSITION PROFILES

(71) Applicant: Applied Materials, Inc., Santa Clara, CA (US)

(72) Inventors: M. Arif Zeeshan, Manchester-by-the-sea, MA (US); Shantanu Kallakuri, Ithaca, NY (US); Joseph C. Olson, Beverly, MA (US)

(73) Assignee: Applied Materials, Inc., Santa Clara, CA (US)

(21) Appl. No.: 17/072,130

(22) Filed: Oct. 16, 2020

(51) Int. Cl. C23C 16/56; C23C 16/04

(52) U.S. Cl. CPC C23C 16/56; C23C 16/042

(57) ABSTRACT

Embodiments of the present disclosure include positioning a mask over a substrate, wherein the mask has a planar surface separated from a top surface of the substrate by a mask distance, and wherein a mask opening is provided through the planar surface. The method may further include positioning a mask element across the mask opening, the mask element including one or more solid portions and one or more openings, and depositing, through the mask opening, a deposition material onto the substrate, wherein the deposition material has a variable profile as a result of the one or more solid portions and the one or more openings.

### FIELD OF THE DISCLOSURE

The present disclosure generally relates to the development of variable deposition profiles for augmented/virtual reality, meta-surfaces, or other optical hardware. More specifically, the disclosure relates to masks and masking techniques to produce variable deposition profiles.

### BACKGROUND OF THE DISCLOSURE

In various applications, such as augmented reality, virtual reality, holographics, and waveguides, one or more lithography processes are often used to achieve a target deposition profile. For example, forming a complex deposition profile having different depths across the surface of a substrate has conventionally been performed via a series of lithographic steps, such as gray-tone lithography, used in combination with subtractive manufacturing and wet etch-dry etch combinations. However, this process is time-consuming and complex, for example, due to dependence on etch chemistry and/or selectivity, which adds considerable costs to devices fabricated using the process.

Accordingly, improved methods and related equipment are needed for forming complex target deposition profiles on substrates.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In some embodiments, a method may include positioning a mask over a substrate, wherein the mask has a planar surface separated from a top surface of the substrate by a mask distance, and wherein a mask opening is provided through the planar surface. The method may further include positioning a mask element across the mask opening, the mask element including one or more solid portions and one or more openings, and depositing, through the mask opening, a deposition material onto the substrate, wherein the deposition material has a variable profile as a result of the one or more solid portions and the one or more openings.

In some embodiments, a mask for variable deposition profiles may include a planar plate with a mask opening, a mask element with one or more solid portions and a set of openings, wherein the mask element extends across at least a portion of the mask opening. The mask element is arranged to block deposition of a deposition material onto one or more portions of a substrate to produce a target deposition profile of the deposition material.

In some embodiments, a system may include a substrate within a plasma chamber, and a mask positioned over the substrate, wherein the mask includes a planar plate with a mask opening, and a mask element with one or more solid portions and a set of openings, wherein the mask element extends across at least a portion of the mask opening, and wherein the mask element is arranged to control deposition of a deposition material onto one or more portions of the substrate to produce a target deposition profile of the deposition material.

### BRIEF DESCRIPTION OF THE DRAWINGS

The accompanying drawings illustrate exemplary approaches of the disclosure, including the practical application of the principles thereof, as follows:

FIG. 1 illustrates an exemplary system and operating environment for forming a device, according to embodiments of the present disclosure.

FIG. 2A illustrates an exemplary mask and substrate according to embodiments of the present disclosure;

FIG. 2B illustrates generation of a plasma within the system according to embodiments of the present disclosure;

FIG. 2C illustrates a deposition atop the substrate according to embodiments of the present disclosure;

FIG. 2D illustrates straight down (e.g., vertical) etch processing of the deposition through a patterned hardmask according to embodiments of the present disclosure;

FIG. 2E illustrates post directional etch processing of the deposition according to embodiments of the present disclosure;

FIG. 2F illustrates post angled etch processing of the deposition according to embodiments of the present disclosure;

FIG. 3 is a diagram illustrating an exemplary mask stitching of various target deposition profiles for an exemplary mask, according to embodiments of the present disclosure;

FIG. 4A illustrates an exemplary mask according to embodiments of the present disclosure;

FIG. 4B illustrates an exemplary mask with an opening and layer(s), according to embodiments of the present disclosure;

FIG. 4C is a diagram illustrating an exemplary target deposition profile according to embodiments of the present disclosure;

FIG. 4D is a diagram illustrating an exemplary target deposition profile according to embodiments of the present disclosure;

FIG. 4E is a diagram illustrating an exemplary target deposition profile according to embodiments of the present disclosure;

FIG. 5A demonstrates various aspects of mask stitching, according to embodiments of the present disclosure;

FIG. 5B demonstrates various aspects of mask stitching, according to embodiments of the present disclosure;

FIG. 5C demonstrates various aspects of mask stitching, according to embodiments of the present disclosure;

FIG. 5D demonstrates various aspects of mask stitching, according to embodiments of the present disclosure;

FIG. 6A illustrates an exemplary deposition profiles for an electromagnetic metasurface, according to embodiments of the present disclosure;

FIG. 6B illustrates an exemplary deposition profiles for an electromagnetic metasurface, according to embodiments of the present disclosure;

FIG. 6C illustrates an exemplary deposition profiles for an electromagnetic metasurface, according to embodiments of the present disclosure; and

FIG. 7 is a flowchart of a method, according to embodiments of the present disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Apparatuses, systems, and methods in accordance with the present disclosure will now be described more fully hereinafter with reference to the accompanying drawings, where various embodiments are shown. The apparatuses, systems, methods may be embodied in many different forms and are not to be construed as being limited to the embodiments set forth herein. Instead, these embodiments are provided so the disclosure will be thorough and complete, and will fully convey the scope of the apparatuses, systems, and methods to those skilled in the art.

In one or more embodiments of the present disclosure, target deposition profiles and patterns may be obtained by varying one or more of deposition process parameters (e.g., pressure, gas ratios, chemistry), plasma sources (e.g., an inductively coupled plasma (ICP) or a capacitively coupled plasma), masks or mask elements (e.g., variable mask shapes, Moiré stacking, mask rotation, pitch changes and height from substrate), etc. In many embodiments, a plasma gradient is generated using a shadow mask, which causes the plasma density to vary due to the shadowing. In several embodiments, one or more masks may be utilized in the stitching of multiple patterns. Oftentimes the target deposition profiles may be utilized for augmented reality, virtual reality, holographic, and/or waveguide applications, such as for electromagnetic metasurfaces. Embodiments herein are not limited in this context, however.

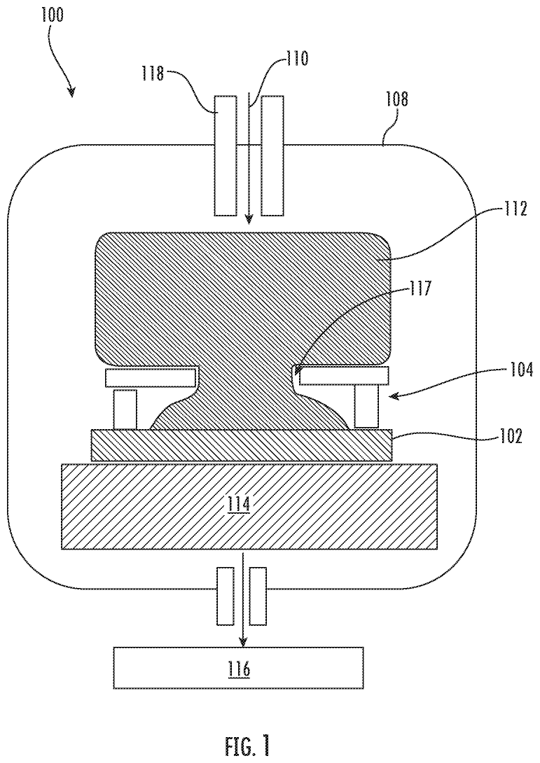

FIG. 1 illustrates a system or operating environment 100 including a shadow mask (hereinafter “mask”) 104 for forming a device according to one or more embodiments of the present disclosure. In various embodiments, operating environment 100 may include a plasma-enhanced chemical vapor deposition (PECVD) device. As shown, operating environment 100 may include a plasma chamber 108 operable with a pump 116 (e.g., a turbo pump). The plasma chamber 108 may include or enclose one or more portions of a substrate 102 and the mask 104, wherein the substrate 102 may be positioned atop a pedestal. A reacting gas 110 may be introduced via one or more gas inlets 118 to generate a deposition plasma 112 within the plasma chamber 108. As will be described in greater detail herein, the deposition plasma 112 may pass through an opening 117 of the mask 104, reaching the substrate 102.

In one or more embodiments of the present disclosure, components of operating environment 100 may be utilized to efficiently obtain target deposition profiles atop the substrate 102. For instance, one or more characteristics of the substrate 102, mask 104, plasma chamber 108, reacting gas 110, gas inlet(s) 118, deposition plasma 112, pedestal 114, and pump 116 may be tuned to efficiently obtain a target deposition profile. In some embodiments, as will be discussed in more detail below, the mask 104 may control or alter the deposition of material onto the substrate 102 to facilitate creation of a target deposition profile of material on the substrate 102. It will be appreciated that the position the mask 104 may be modified relative to the substrate 102. For example, one or more of a target height, angle, rotation, pitch, and slope with respect to the substrate 102 may be configured as desired. In some embodiments, the mask 104 may comprise a metal or metal alloy, such as aluminum. Embodiments herein are not limited in this context.

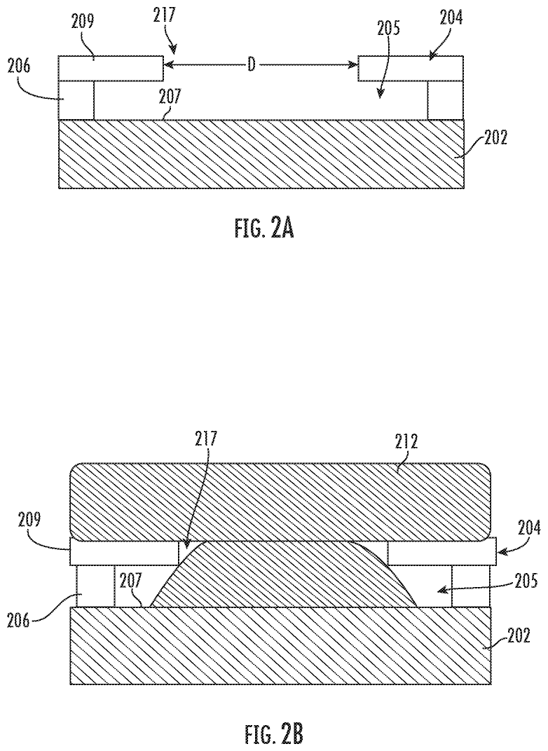

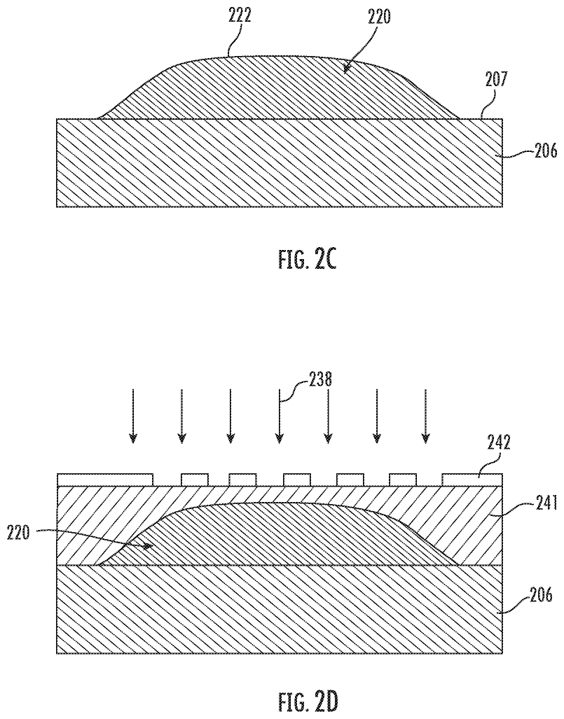

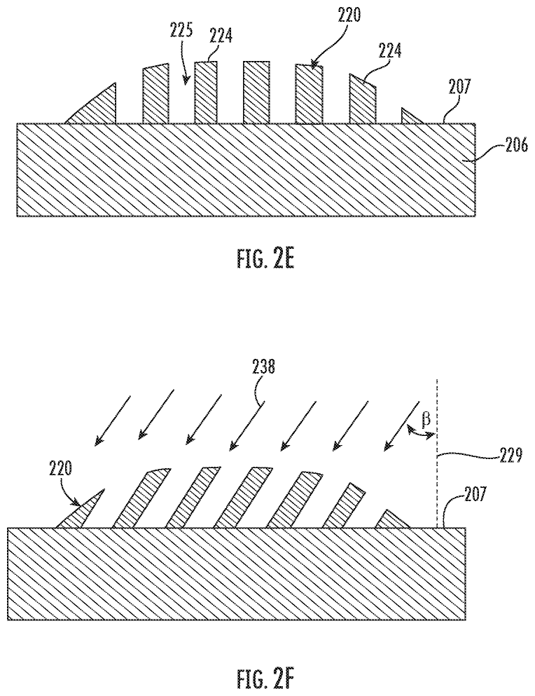

FIGS. 2A-2F illustrate an exemplary process flow for forming a device using variable deposition according to one or more embodiments of the present disclosure. As shown in FIG. 2A, a mask 204 is provided over a substrate 202. Although non-limiting, the substrate 202 may include a wafer, such as a silicon (Si), glass, silicon carbide wafer, gallium arsenide (GaAs), germanium (Ge), indium phosphide (InP), sapphire, among other wafer types. Embodiments herein are not limited in this context. The mask 204 may define an opening 217 and an interior cavity 205 over the substrate 202. The opening 217 may have a diameter or distance ‘D’. It will be appreciated that the distance defining the opening 217 may vary. In some embodiments, the mask 204 may include a spacer 206 and an upper plate 209. As shown, the upper plate 209 may generally be planar and extend substantially parallel to a top surface 207 of the substrate 202. The upper plate 209 may be separated from the top surface 207 of the substrate by a mask distance ‘MD’. MD and D provide additional knobs for tuning the deposition profile.

As shown in FIG. 2B, a deposition plasma 212 may be formed, wherein the deposition plasma 212 extends through the opening 217 of the mask 204 and into the interior cavity 205. The deposition plasma 212 may extend to the top surface 207 of the substrate 202.

As shown by deposit 220 in FIG. 2C, in various embodiments herein, mask 204 and spacer 206 may be utilized in combination with the deposition plasma 212 to create the deposit 220 with a variable deposition profile 222 matching a target deposition profile. For example, due to the size (D) of the opening 217 of the mask 204, the mask distance (MD) between the upper plate 209 and the substrate 202, and shadowing created by the upper plate 209 over the interior cavity 205, the deposit 220 may have a substantially convex deposition profile 222 relative to the top surface 207 of the substrate 202. In some embodiments, the deposit 220 may be further etched to produce the deposition profile 222.

As used herein, the variable deposition profile 222 of the deposit 220 may refer to the shape, thickness, and/or height of the deposit 220 atop the substrate 202. In some embodiments, the variable deposition profile 222 may also refer to characteristics of the deposit 220 including, but not limited to, electromagnetic properties, material, index of refraction, weight, concentration, density, volume, transparency, translucency, cross-section, layers, and the like.

Deposit 220 may include a material that can be applied by a PECVD process. In various embodiments, deposit 220 may comprise a dielectric thin film, such as one or more of silicon mononitride (SiN), silicon carbonitride (SiCN), silicon oxynitride (SiON), silicon dioxide (SiO₂), amorphous silicon (a-Si), polycrystalline silicon (poly-Si), metal oxides, metals, and various alloys. In some embodiments, deposit 220 may comprise a plurality of materials and/or layers.

As shown in FIG. 2D, a patterning layer 241 and a patterned hardmask 242 may be formed over the deposit 220 and then processed 238 (e.g., etched) to produce a plurality of fins 224 and a plurality of trenches 225, as demonstrated in FIG. 2E. As shown, the trenches 225 may extend to the top surface 207 of the substrate 202. In other embodiments, the etch 238 is not selective to the substrate 202. It will be appreciated that a variety of masking and processing schemes may be used to accomplish fin and trench formation.

In another embodiments, as shown in FIG. 2F, the etch 238 may be an angled ion etch (e.g., ribbon beam) delivered to the deposit 220 at a non-zero angle β of inclination relative to a perpendicular 229 extending from the top surface 207 of the substrate 202. Although not shown, in some embodiments, the etch 238 may be performed through the patterning layer 241 and the patterned hardmask 242 of FIG. 2D. Once formed, the fins 224 and the trenches 225 may define a gradient refractive index optic or an electromagnetic metasurface. Embodiments herein are not limited in this context.

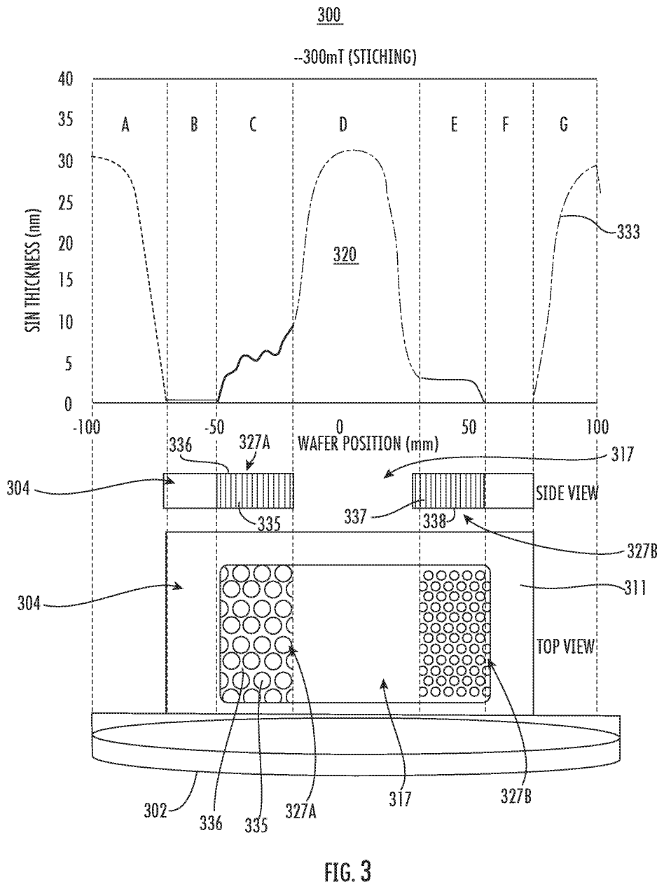

FIG. 3 illustrates a diagram 300 of exemplary mask stitching for target deposition profiles according to one or more embodiments of the present disclosure. Diagram 300 provides an exemplary illustration of how the mask 304 and different mask features can be used to obtain complex deposition profile 333 of a deposition material 320. Specifically, diagram 300 illustrates the deposition profile 333 as it relates to portions ‘A’, ‘B’, ‘C’, ‘D’, ‘E’, ‘F’. and ‘G’ of wafer substrate 302 due to mask 304. For example, the mask 304 may include an exterior portion 311, which is generally solid or non-porous. As a result, the deposition material 320 will generally be prevented from reaching the substrate 302 in those areas beneath the exterior portion 311 of the mask 304 due to decreased plasma density.

The mask 304 may further include an opening 317, wherein the deposition material 320 may generally pass freely through the opening 317 to the substrate 302. A first interior portion 327A may include a first plurality of openings 335 extending through a first plate 336, while a second interior portion 327B may include a second plurality of openings 337 through a second plate 338. In some embodiments, a size (e.g., diameter) of the first and second plurality of openings 335, 337 may be the same or different. As demonstrated in portion ‘C’, larger-sized openings 335 generally allow more of the deposition material 320 to pass through the first plate 336 and reach the substrate 302. As demonstrated in portion ‘E’, smaller-sized openings 337 generally allow less of the deposition material 320 to pass through the second plate 338 and reach the substrate 302. The smaller-sized openings 337 provide additional control over the resolution of the profile 333. In other words, the smaller the diameter of the openings, the higher the resolution.

It will be appreciated that mask 304 represents one non-limiting example. For example, although the first and second plurality of openings 335, 337 are shown as being circular, any variety of opening shape/profile may be possible. Furthermore, in various embodiments, different target deposition profiles may be obtained through intricate shape stitching in the mask 304. For example, the mask 304 may include a protruding structure or feature (not shown), such as a flap, covering, overhang, tab, etc., which covers or partially covers any one of opening 317, openings 335, and openings 337, and which extends away from the mask 304. Although non-limiting, the feature may include a fixed end coupled to the mask 304 and a free end angling away from the mask 304. As a result, plasma of the deposition material 320, which may have a uniform density above the mask 304, may have a gradient density in an area beneath the feature and above a processing area of the substrate 302.

It will be appreciated that the feature of the mask 304 may take on a variety of shapes and configurations in various embodiments. By varying the shape, configuration, and/or distance of the feature from the mask 304, as well as by varying a width, height and/or size of the corresponding opening, the plasma density gradient in the area beneath the feature and above the processing area may also be varied.

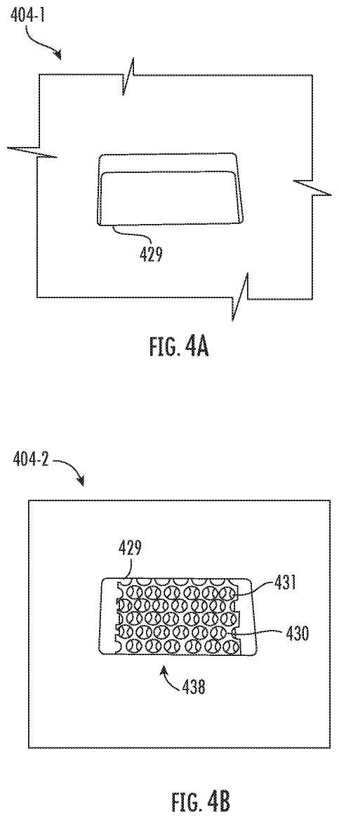

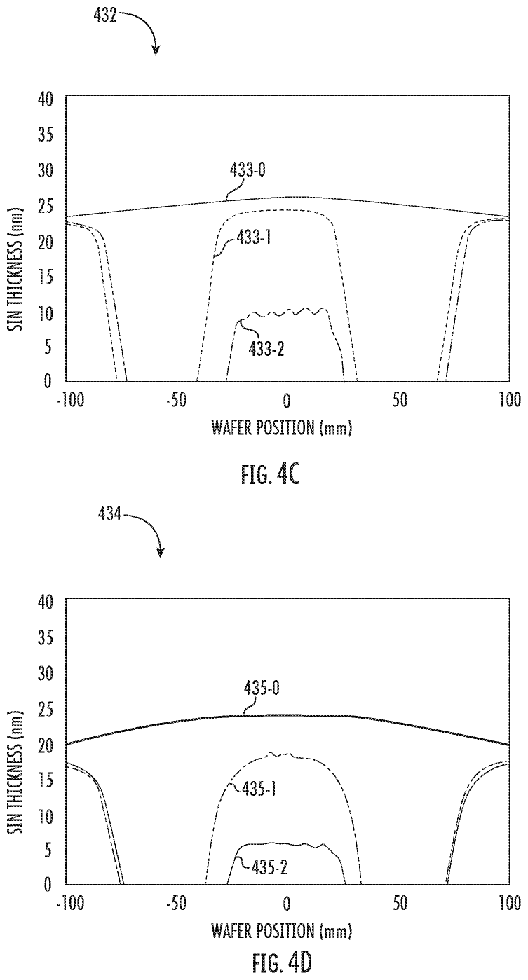

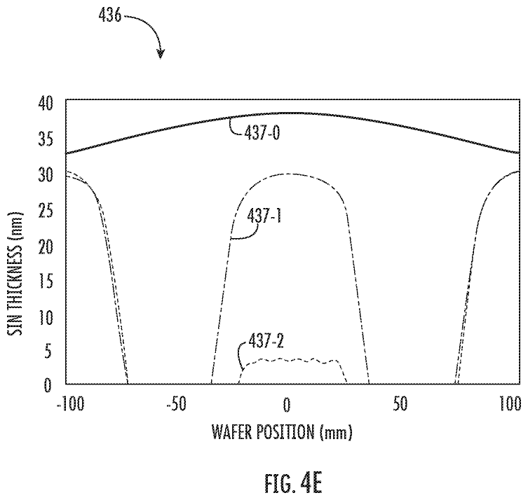

FIGS. 4A-4E illustrate masks 404-1, 404-2 with corresponding deposition profiles according to one or more embodiments of the present disclosure. FIG. 4A includes mask 404-1 with mask opening 429. FIG. 4B includes mask 404-2 with mask opening 429 and layer 438 comprising mask element(s) 430 with shaped openings 431. In some embodiments, multiple mask elements may be placed atop/over one another. FIG. 4C includes a non-limiting deposition chart 432 with deposition profiles 433-0, 433-1, 433-2 (collectively deposition profiles 433) created at, for example, 6 millitorr (mT) of pressure for no mask, mask 404-1, and mask 404-2, respectively. FIG. 4D includes a deposition chart 434 with deposition profiles 435-0, 435-1, 435-2 (collectively deposition profiles 435) created at, for example, 60 mT of pressure for no mask, mask 404-1, and mask 404-2, respectively. FIG. 4E includes a deposition chart 436 with deposition profiles 437-0, 437-1, 437-2 (collectively deposition profiles 437) created at, for example, 300 mT of pressure for no mask, mask 404-1, and mask 404-2, respectively. Accordingly, various target deposition profiles may be obtained by tuning characteristics including one or more of pressure, gas flows, power to the electrodes (e.g., radio frequency (RF) power), flow ration controller, and masks. For example, one or more of these characteristics may be tuned to modulate the thickness and/or uniformity of a deposition profile.

Masks 404-1, 404-2 may comprise a planar surface with one or more mask openings 429. In some embodiments, masks 404-1, 404-2 may include one or more layers (e.g., layer 438 comprising mask element(s) 430) covering one or more portions of the mask opening(s) 429. In other embodiments, masks 404-1, 404-2 may not include any layers covering one or more portions of the mask opening 429. In the illustrated embodiments, the mask opening 429 is rectangular. In other embodiments, the mask opening 429 may have any geometric shape, such as circular, triangular, and the like, or a combination thereof. As shown in FIG. 4B, in addition to the components of mask 404-1, mask 404-2 may include layer 438 comprising mask elements 430 with shaped openings 431. In the illustrated embodiment, the mask elements 430 comprise a patterned-grid or mesh with circular shaped openings covering a middle portion of the mask opening 429. In other embodiments, the shaped openings 431 may have any geometric shape, such as rectangular or triangular, or a combination thereof.

When no mask is present over the substrate, deposition profiles 433-0, 435-0, 437-0, which have a relatively uniform thickness, may result. The deposition profiles 433-0, 435-0, 437-0 may be referred to as having one deposit component. The relatively uniform thickness may be the thickest in the middle and the thinnest at the extents.

Mask 404-1 (FIG. 4A) can result in deposition profiles 433-1, 435-1, 437-1, which have a central hump and additional humps at the extents with roughly the same thickness as the central hump. The deposition profiles 433-1, 435-1, 437-1 may be referred to as having five deposit portions with a first deposit portion comprising the hump proximate the −100 mm extent of the charts, a second deposit portion comprising the zero thickness portion proximate the −50 mm portion of the charts, a third deposit portion comprising the central hump proximate the 0 mm portion of the charts, a fourth deposit portion comprising the zero thickness portion proximate the 50 mm portion of the charts, and a fifth deposit portion comprising the hump proximate the 100 mm extent of the charts. In various embodiments, the central hump (e.g., third deposit portion) may result from the mask opening 429 of mask 404-1, the additional humps (e.g., first and fifth deposit components) may result from being beyond the extents of the planar surface of the mask 404-1, and the zero thickness portions (e.g., second and fourth deposit components) may result from the solid planar surface of the mask 404-1.

Mask 404-2 can result in deposition profiles 433-2, 435-2, 437-2, which have a central hump and additional humps at the extents with a greater thickness than the central hump. The deposition profiles 433-2, 435-2, 437-2 may be referred to as having five deposit portions with a first deposit portion comprising the hump proximate the −100 mm extent of the charts, a second deposit portion comprising the zero thickness portion proximate the −50 mm portion of the charts, a third deposit portion comprising the central hump proximate the 0 mm portion of the charts, a fourth deposit portion comprising the zero thickness portion proximate the 50 mm portion of the charts, and a fifth deposit portion comprising the hump proximate the 100 mm extent of the charts. In various embodiments, the central hump (e.g., third deposit portion) may result from layer 438 covering a portion of the mask opening 429 of mask 404-2, the additional humps (e.g., first and fifth deposit portion) may result from being beyond the extents of the planar surface of the mask 404-2, and the zero thickness portions (e.g., second and fourth deposit portions) may result from the solid planar surface of the mask 404-2. Additionally, the reduced thickness of the central hump (e.g., third deposit portion) and the individual crests along a top thereof may result from shaped openings 431 of layer 438 of shaped openings 431 of the mask element(s) 430.

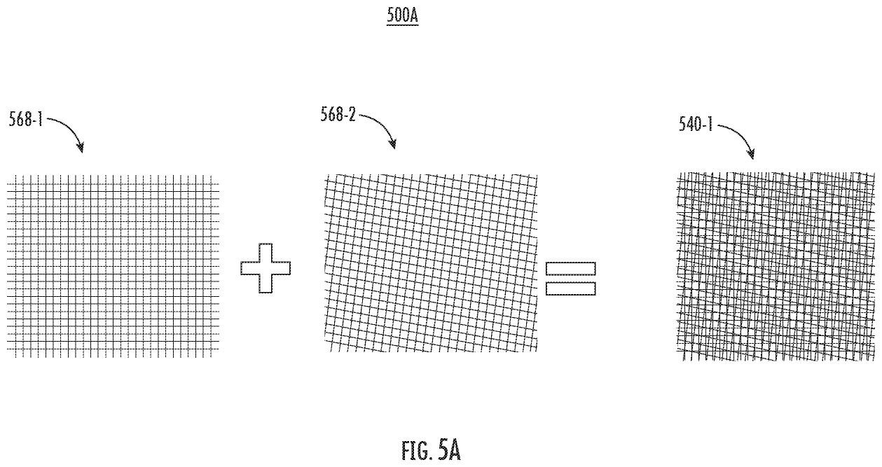

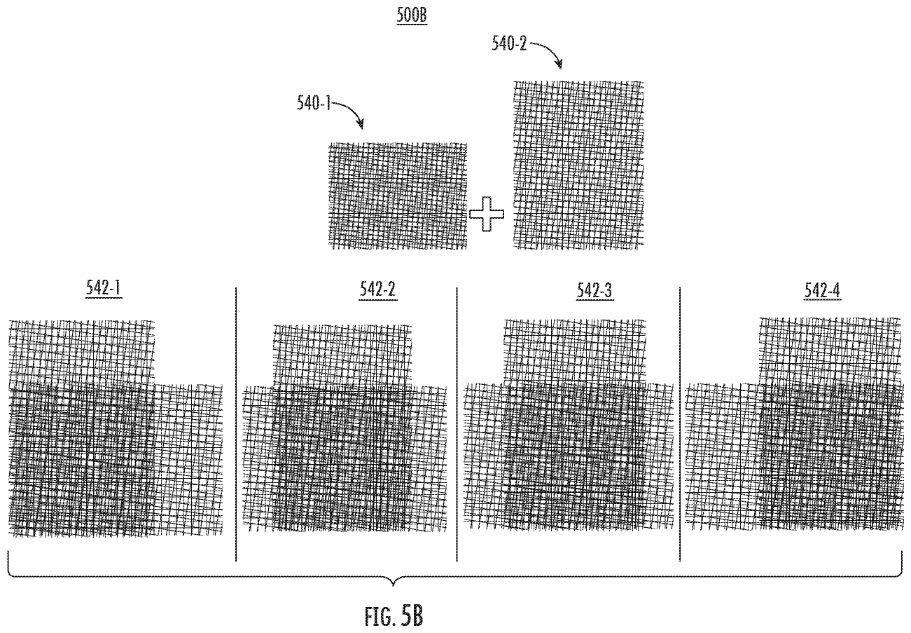

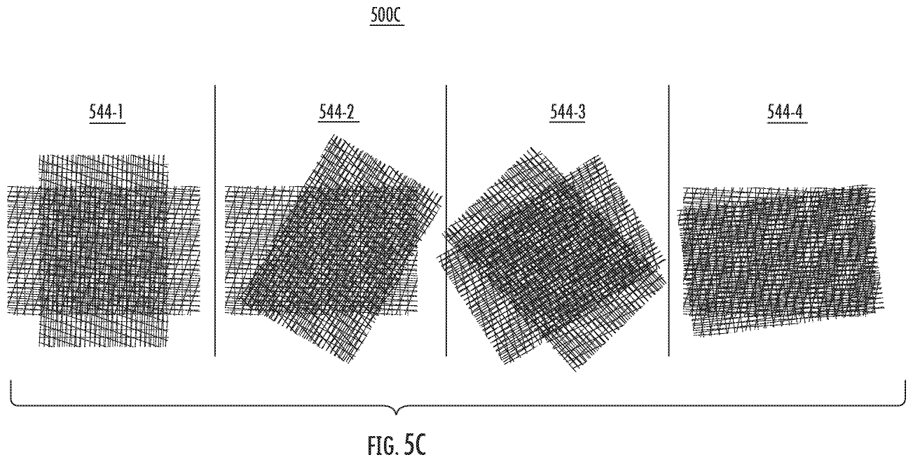

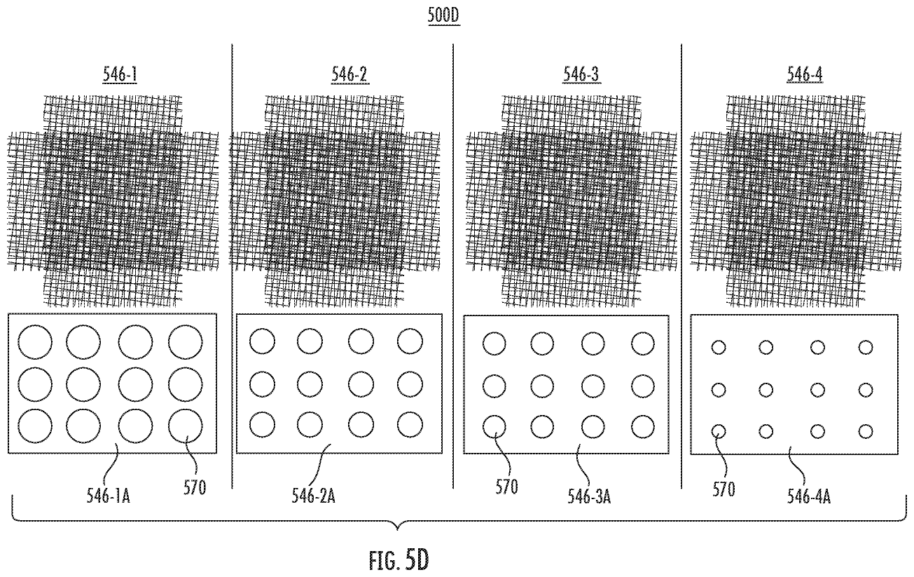

FIGS. 5A-5D illustrate various examples of mask stitching according to one or more embodiments of the present disclosure. Mask stitching, as of the present disclosure, may include designing, stacking, orienting, and/or positioning a plurality of layers, or mask elements, in a mask utilized to limit deposition of a material onto a substrate to obtain a target deposition profile on the substrate. As shown, mask 500A of FIG. 5A includes layers (or mask elements) 568-1, 568-2 to form stacked compound layer 540-1. Mask 500B of FIG. 5B includes layers (or mask elements) 540-1, 540-2, which are stacked and translated to form layer sets 542-1, 542-2, 542-3, and 542-4. Mask 500C of FIG. 5C includes layers (or mask elements) 540-1, 540-2, which are stacked and rotated to form layer sets 544-1, 544-2, 544-3, and 544-4. Mask 500D of FIG. 5D includes stacking one or more of layer set 544-1 (FIG. 5C) to form layer stacks 546-1, 546-2, 546-3, and 546-4.

In some embodiments, mask layer/element stitching may be utilized to obtain Moiré patterned deposits. Further, mask elements, or layers, may comprise one or more meshes of various sizes. For example, micron-sized meshes and/or stacked masks (or stacked layers) may be used to obtain Moiré patterned deposits with finer feature control. In FIG. 5A, layers 568-1, 568-2 may comprise patterned grids with square openings. Layer 568-2 may be rotated at an angle with respect to layer 568-1. For example, layer 568-2 may be rotated by 20 degrees with respect to layer 568-1. Layer 568-1 and layer 568-2 are stacked to form compound layer 540-1, which has a patterned-grid with a variety of different shaped openings. In yet other embodiments, one or more of the layers may be a layer of glass including a plurality of openings therethrough.

Compound layers may also be stacked and translated and/or rotated with other layers or compound layers to produce layer sets. For example, in FIGS. 5B and 5C, various translated and/or rotated versions of compound layer 540-1 are stacked to produce layer sets. More specifically, in FIG. 5B, compound layer 540-1 is stacked with compound layer 540-2, which is rotated 90 degrees and translated by different distances with respect to compound layer 540-1, to produce layer sets 542-1, 542-2, 542-3, 542-4. In FIG. 5C, compound layer 540-1 is stacked with compound layer 540-2, which are rotated at different angles with respect to compound layer 540-1, to produce layer sets 544-1, 544-2, 544-3, 544-4. Accordingly, multiple different patterns can be obtained by translating and/or rotating multiple layers (e.g., two or more layers of the same pattern or different patterns) with respect to one another. Further translating and/or rotating can be utilized to obtain shape and pitch variations in deposition profiles.

Furthermore, in some embodiments, layer sets may also be stacked to form layer stacks, such as for finer feature control. Referring to FIG. 5D, layer stack 546-1 may comprise layer set 544-1, layer stack 546-2 may comprise two layer sets 544-1 stacked on top of one another, layer stack 546-3 may comprise three layer sets 544-1 stacked on top of one another, and layer stack 546-4 may comprise four layer sets 544-1 stacked on top of one another. It will be appreciated that layer stacks 546-1A, 546-2A, 546-3A, and 546-4A represent simplified versions of layer stacks 546-1, 546-2, 546-3, and 546-4, respectively, wherein an effective average opening size of openings 570 decreases as more layers are added to the stack(s).

Accordingly, stacking copies of the same pattern on top of one another can provide finer feature control. One of ordinary skill in the art will appreciate that distinctions between layers, compound layers, layer sets, and layer stacks herein are for clarity of description, but more generally the terms may be used interchangeably. For example, a layer may comprise or refer to a compound layer, a layer set, or a layer stack.

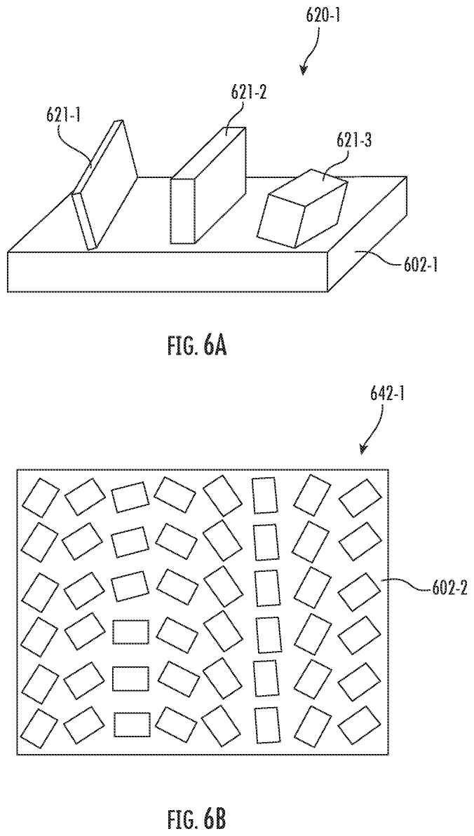

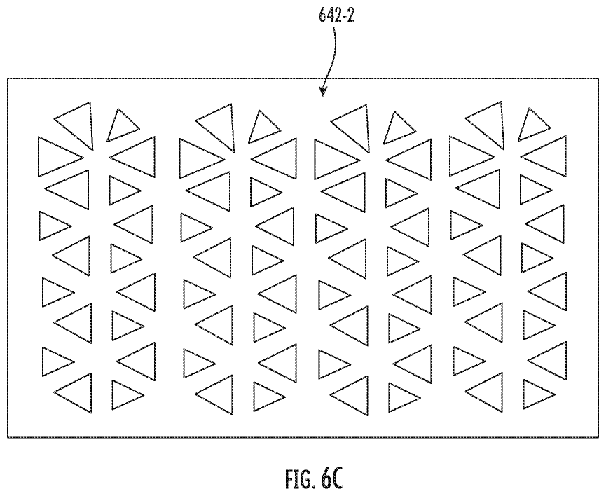

FIGS. 6A-6C illustrate various exemplary deposition profiles for electromagnetic metasurfaces according to one or more embodiments of the present disclosure. FIG. 6A includes a perspective view of deposit 620-1 comprising deposit components 621-1, 621-2, 621-3 on substrate 602-1. FIG. 6B includes a top view of a target deposition profile 642-1 on substrate 602-2. FIG. 6C includes a top view of a target deposition profile 642-2. In one or more embodiments, target deposition profiles 842-1 and 842-2 may comprise electromagnetic metasurfaces. In many embodiments, one or more components illustrated in FIGS. 6A-6C, or described with respect thereto, may be the same or similar in construction, function, and/or appearance as one or more other components of the present disclosure. Embodiments are not limited in this context.

In many embodiments, a deposit, or deposition profile, may include one or more deposit components. In many such embodiments, the one or more deposit components may be discrete or continuous. In FIG. 6A, deposit 620-1 includes three discrete deposit components 621-1, 621-2, 621-3 (collectively deposit components 621) on substrate 602-1. One or more characteristics of the deposit components 621 can be controlled or tailored by mask stitching or controlling other aspects of the deposition process, as described herein. For example, one or more of the size, shape, height, width, thickness, angle, and rotation of a deposit component 621 can be configured through mask stitching and/or controlling other aspects of the deposition process to obtain a target deposition profile. In some embodiments, a target deposition profile comprising a plurality of deposit components may form a metasurface, such as an electromagnetic metasurface.

An electromagnetic metasurface may include a thin film materials with sub-wavelength thickness to allow for exotic optical/electromagnetic properties. More generally, metasurfaces may modulate behaviors of electromagnetic waves through specific boundary conditions. In some embodiments, metasurfaces may be the same as or similar to a two-dimensional version of a three-dimensional metamaterial. Metasurfaces may be structured with scaled patterns of constant/variable height (see e.g., FIGS. 6B-6C). In several embodiments, the scaled patterns of constant/variable height may be deposited using variable deposition through micron masks. In one or more embodiments, a metasurface may control how light reflects or refracts off the metasurface, such as based on wavelength, polarity, frequency, or angle of incidence. For example, metasurface light dispersion may be utilized to control the wavelength of light based on the angle of incidence of the light.

Target deposition profile 642-1 on substrate 602-2 illustrates a first exemplary deposition profile that may be obtained through mask stitching and/or controlling other aspects of the deposition process. Target deposition profile 642-1 incorporates a variety of discrete deposition components arranged to form a metasurface. Target deposition profile 642-2 illustrates a second exemplary deposition profile for a metasurface that may be obtained through mask stitching and/or controlling other aspects of the deposition process.

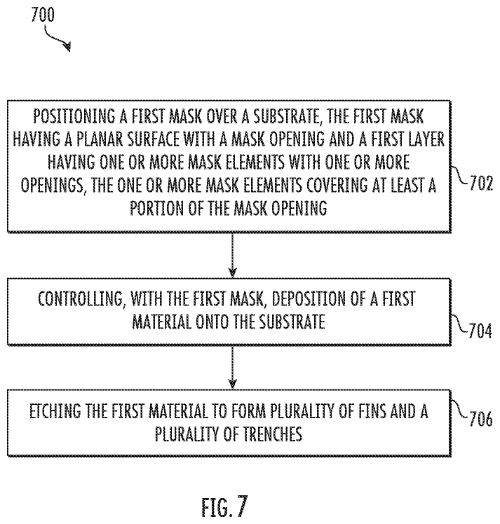

Turning to FIG. 7, a method 700 according to embodiments of the present disclosure will be described. As shown, at block 702, the method 700 may include positioning a mask over a substrate, wherein the mask has a planar surface separated from a top surface of the substrate by a mask distance, and wherein a mask opening is provided through the planar surface. At block 704, the method 700 may include positioning a mask element across the mask opening, the mask element including one or more solid portions and one or more openings.

In some embodiments, a second mask element is positioned across the mask opening, wherein the second mask element includes one or more second openings. In some embodiments, the mask element and the second mask element are stacked relative to one another. In some embodiments, the mask element and the second mask element are rotated/translated relative to one another to limit deposition of the first material onto the first target portion of the substrate. In some embodiments, the method includes varying a diameter between the one or more openings of the mask element and the one or more second openings of the second mask element. In some embodiments, the mask element and the second mask element may be positioned between the planar surface of the mask and the top surface of the substrate.

At block 706, the method 700 may include depositing, through the mask opening, a deposition material onto the substrate, wherein the deposition material has a variable profile as a result of the one or more solid portions and the one or more openings.

At block 708, the method 700 may optionally include etching the first material to form plurality of fins and a plurality of trenches. In some embodiments, the etch is a vertical etch. In some embodiments, the etch is an angled ion (e.g., ribbon beam) delivered at a non-zero angle of inclination relative to a perpendicular to a top surface of the substrate. Once formed, the plurality of fins and plurality of trenches may be part of an optical grating with slanted fins/structures. Embodiments herein are not limited in this context.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

In various embodiments, design tools can be provided and configured to create datasets used to obtain target deposition profiles. For example, data sets can be created to determine mask and/or process characteristics to obtain a target deposition profile. In some such examples, the data sets may be created based on historical data from previous depositions. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules of the present disclosure might be implemented as discrete modules or the functions and features described can be shared in part or in total among one or more modules. In other words, as would be apparent to one of ordinary skill in the art after reading the description, the various features and functionality of the present disclosure may be implemented in any given application. Furthermore, the various features and functionality can be implemented in one or more separate or shared modules in various combinations and permutations. Although various features or elements of functionality may be individually described or claimed as separate modules, one of ordinary skill in the art will understand these features and functionality can be shared among one or more common software and hardware elements.

By utilizing the embodiments of the present disclosure, target deposition profiles and patterns may be efficiently obtained by combining (e.g., via stacking, rotating, translating, displacing) masks and/or mask elements relative to one or more other components, such as masks, mask elements, and substrates. Oftentimes this may include one or more of selecting the shapes and patterns utilized in one or more layers of a mask, the orientation of a layer relative to one or more other layers, and the spacing of the mask relative to a substrate to apply the target deposition profile. A first technical advantage of the masks and mask elements of the present embodiments includes improved manufacturing efficiency by eliminating more time consuming, costly, and difficult processes, such as gray-tone lithography, to achieve target deposition profiles.

Further, a second technical advantage of the present embodiments includes applicability to a wide range of chemistries, such as to efficiently accommodate a variety of etching methods. In many embodiments, utilization of an additive line-of-sight deposition process based on plasma gradients may allow a wide variety of dielectric films, such as SiN, SiCN, SiON, SiO₂, amorphous-Si, and metals, to be used in deposition profiles. Further, additive line-of-sight deposition processes can remove complexity of subtractive methods, such as where final profiles are dependent on the etching chemistry, selectivity, and are only valid for a specific material or combination of materials.

The present disclosure is not to be limited in scope by the specific embodiments of the present disclosure. Indeed, other various embodiments of and modifications to the present disclosure, in addition to those of the present disclosure, will be apparent to those of ordinary skill in the art from the foregoing description and accompanying drawings. Thus, such other embodiments and modifications are intended to fall within the scope of the present disclosure. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as of the present disclosure.

1. A method, comprising:
positioning a mask over a substrate, wherein the mask has a planar surface separated from a top surface of the substrate by a mask distance, wherein the planar surface is connected a spacer, wherein the spacer extends to the top surface of the substrate, and wherein a mask opening is provided through the planar surface;
positioning a mask element across the mask opening, the mask element including one or more solid portions and one or more openings; and
depositing, through the mask opening, a deposition material onto the substrate, wherein the deposition material has a variable profile as a result of the one or more solid portions and the one or more openings.

2. The method of claim 1, further comprising etching the deposition material to form a plurality of fins and a plurality of trenches.

3. The method of claim 2, wherein etching the deposition material comprises delivering an ion beam to the substrate at a non-zero angle of inclination relative to a perpendicular extending from the top surface of the substrate.

4. The method of claim 2, wherein etching the deposition material comprises performing a vertical etch.

5. The method of claim 1, further comprising positioning a second mask element across the mask opening, wherein the second mask element includes one or more second openings.

6. The method of claim 5, further comprising stacking the mask element and the second mask element relative to one another.

7. The method of claim 5, further comprising varying a diameter between the one or more openings of the mask element and the one or more second openings of the second mask element.

8. The method of claim 5, further comprising positioning the mask element and the second mask element between the planar surface of the mask and the top surface of the substrate.

9. The method of claim 5, comprising translating the mask element and the second mask element relative to one another to limit deposition of the deposition material onto the substrate.

10. A mask for variable deposition profiles, comprising:
a planar plate with a mask opening;
a mask element with one or more solid portions and a set of openings, the mask element extending across at least a portion of the mask opening; and
wherein the mask element is arranged to block deposition of a deposition material onto one or more portions of a substrate to produce a target deposition profile of the deposition material.

11. The mask of claim 10, wherein the mask element is a mesh extending across the mask opening.

12. The mask of claim 10, wherein the planar plate and the mask element are separated from a top surface of the substrate by a vertical mask distance.

13. The mask of claim 10, further comprising a second mask element extending across the mask opening, wherein the second mask element includes a set of second openings.

14. The mask of claim 13, wherein mask element and the second mask element are stacked relative to one another, and wherein at least one of the set of openings is aligned with at least one of the set of second openings.

15. A system, comprising:
a substrate within a plasma chamber; and
a mask positioned over the substrate, the mask comprising:
a planar plate with a mask opening; and
a mask element with one or more solid portions and a set of openings, the mask element extending across at least a portion of the mask opening, wherein the mask element is arranged to control deposition of a deposition material onto one or more portions of the substrate to produce a target deposition profile of the deposition material.

16. The system of claim 15, further comprising a second mask element positioned across the mask opening, wherein the second mask element includes a set of second openings.

17. The system of claim 16, wherein the mask element and the second mask element are stacked relative to one another.

18. The system of claim 16, wherein a diameter of at least one opening of the set of openings of the mask element is different than a diameter of at least one opening of the set of second openings of the second mask element.

19. The system of claim 16, further comprising positioning the mask element and the second mask element between the planar plate of the mask and a top surface of the substrate.

20. The system of claim 16, comprising translating the mask element and the second mask element relative to one another to limit deposition of the deposition material on the substrate.
